(19) United States
(12) Patent Application Publication
(10) Pub. No.: US 2026/0035790 A1
(43) Pub. Date: Feb. 5, 2026

(54) DEPOSITION APPARATUS

(71) Applicant: SAMSUNG ELECTRONICS CO., LTD., Suwon-si (KR)

(72) Inventors: Woohyun Kim, Suwon-si (KR); Woo-Hee Kim, Ansan-si (KR); Joonmyeong Choi, Suwon-si (KR); Jeong-min Lee, Ansan-si (KR)

(73) Assignee: INDUSTRY-UNIVERSITY COOPERATION FOUNDATION HANYANG UNIVERSITY ERICA CAMPUS, Ansan-si (KR)

(21) Appl. No.: 19/020,636

(22) Filed: Jan. 14, 2025

(30) Foreign Application Priority Data
Aug. 1, 2024 (KR) 10-2024-0102569

(51) Int. Cl. C23C 16/455; C23C 16/44; C23C 16/458; C23C 16/52; C23C 16/54

(52) U.S. Cl. CPC C23C 16/45544; C23C 16/4408; C23C 16/4586; C23C 16/52; C23C 16/54

(57) ABSTRACT

An example deposition apparatus includes a chamber, a voltage generator, a precursor supplier, a reactant supplier, and a controller. The chamber is configured to accommodate a voltage applicator comprising a stage that accommodates a substrate. The voltage generator is electrically connected with the stage in order for bias voltage to be applied to the substrate. The precursor supplier is configured to supply precursor into the chamber. The reactant supplier is configured to supply reactant into the chamber. The controller is configured to control the bias voltage applied to the substrate, precursor flow, and reactant flow.

### CROSS-REFERENCE TO RELATED APPLICATION

This application claims the benefit of Korean Patent Application No. 10-2024-0102569, filed on Aug. 1, 2024, in the Korean Intellectual Property Office, the disclosure of which is incorporated herein by reference.

### BACKGROUND

Semiconductor processes include the process of manufacturing various thin films. The process of manufacturing thin films can generally be carried out through deposition. With regard to the deposition, chemical vapor deposition (CVD), physics vapor deposition (PVD), and atomic layer deposition (ALD) are known.

With the ALD, the thin film thickness can be controlled and with low process temperature, deformation of the thin film is reduced, compared to the CVD and the PVD.

Meanwhile, with the ALD, when the activation energy is high, impurities contained in the precursor remain within the formed thin film, thus increasing the resistivity. Further, when solid precursor is used, as the surface area of the solid precursor changes due to sublimation, the concentration of the precursor flowing into the chamber changes, and thus the impingement rate decreases.

### SUMMARY

The present disclosure relates to a deposition apparatus by which impingement rate of the precursor is prevented from decreasing by using an electric field bias during deposition and the resistivity is reduced by lowering the activation energy during ligand exchange.

The technical tasks to be achieved by the present example implementations are not limited to the technical tasks described above, and other technical tasks may be inferred from the following example implementations by those skilled in the art.

In some implementations, a deposition apparatus includes a chamber configured to accommodate a voltage applicator including a stage that is configured to accommodate a substrate, a voltage generator that is electrically connected with the stage and configured to apply bias voltage to the substrate, a precursor supplier configured to supply precursor into the chamber, a reactant supplier configured to supply reactant into the chamber, and a controller configured to control the bias voltage applied to the substrate, precursor flow and reactant flow, wherein the controller is configured to, for each sub-cycle of a plurality of sub-cycles: cause the precursor supplier to supply the precursor into the chamber, cause the chamber to purge remaining precursor that is not bound to the substrate in the chamber, cause the reactant supplier to supply the reactant into the chamber, and cause the chamber to purge remaining reactant that is not reacted with the precursor in the chamber and by-product of reaction, and wherein the controller is configured to: for each positive polarity sub-cycle of a super cycle, cause a positive electric field bias to be applied to the substrate based on the precursor being supplied into the chamber, and for each negative polarity sub-cycle of the super cycle, cause a negative electric field bias to be applied to the substrate based on the precursor being supplied into the chamber.

In some implementations, a deposition apparatus includes a chamber configured to accommodate a voltage applicator, the voltage applicator including a stage that is configured accommodate a substrate, a voltage generator that is electrically connected with the stage and configured to apply bias voltage to the substrate, a precursor supplier configured to supply precursor including central metal into the chamber, the precursor including central metal, a reactant supplier configured to supply reactant into the chamber, and a controller configured to control the bias voltage applied to the substrate, precursor flow and reactant flow, wherein the controller is configured to, for each sub-cycle of a plurality of sub-cycles: cause the precursor supplier to supply the precursor into the chamber, cause the chamber to purge remaining precursor that is not bound to the substrate in the chamber, cause the reactant supplier to supply the reactant into the chamber, and cause the chamber to purge remaining reactant that is not reacted with the precursor in the chamber and by-product of reaction, wherein the controller is configured to: for each positive polarity sub-cycle of a super cycle, cause a positive electric field bias to be applied to the substrate based on the precursor being supplied into the chamber, and for each negative polarity sub-cycle of the super cycle, cause a negative electric field bias to be applied to the substrate based on the precursor being supplied into the chamber, and wherein the controller is configured to cause an ionic compound of the central metal to be deposited on the substrate, thereby forming a deposition layer.

In some implementations, a deposition apparatus includes a chamber configured to accommodate a voltage applicator, the voltage applicator including a stage that is configured to accommodate a substrate, a voltage generator that is electrically connected with the stage and configured to apply bias voltage to the substrate, a precursor supplier configured to supply precursor including central metal into the chamber, a reactant supply part configured to supply reactant into the chamber, and a controller configured to control the bias voltage applied to the substrate, precursor flow and reactant flow, wherein the controller is configured to, for each sub-cycle of a plurality of sub-cycles: cause the precursor supplier to supply the precursor into the chamber, cause the chamber to purge remaining precursor that is not bound to the substrate in the chamber, cause the reactant supplier to supply the reactant into the chamber, and cause the chamber to purge remaining reactant that is not reacted with the precursor in the chamber and by-product of reaction, wherein the controller is configured to: for each positive polarity sub-cycle of a super cycle, cause a positive electric field bias to be applied to the substrate based on the precursor being supplied into the chamber, and for each negative polarity sub-cycle of the super cycle, cause a negative electric field bias to be applied to the substrate based on the precursor being supplied into the chamber, wherein the controller is configured to: cause precursor nuclei to be formed on the substrate based on performing the positive polarity sub-cycle, cause a continuous deposition layer to be formed based on connecting the precursor nuclei formed on the substrate based on performing the negative polarity sub-cycle, and wherein the controller is configured to: control the super cycle to start with the positive polarity sub-cycle, perform the positive polarity sub-cycle repeatedly until the precursor nuclei covers 50% or more of a surface of the substrate when staring with the positive polarity sub-cycle, and perform the negative polarity sub-cycle repeatedly until for the continuous deposition layer covers an entire surface of the substrate and thickness of the continuous deposition layer increases.

Additional aspects of example implementations will be set forth in part in the description which follows and, in part, will be apparent from the description, or may be learned by practice of the disclosure.

According to example implementations, it is possible to provide a deposition apparatus by which impingement rate of the precursor is prevented from decreasing by using an electric field bias during deposition and the resistivity is reduced by lowering the activation energy during ligand exchange.

The effect of the example implementations are not limited to the above-described effects, and other effects not described would be clearly understood by those skilled in the art from the description of the claims.

### BRIEF DESCRIPTION OF THE DRAWINGS

These and/or other aspects, features, and advantages of the present disclosure will become apparent and more readily appreciated from the following description of example implementations, taken in conjunction with the accompanying drawings.

FIG. 1 is a plan view illustrating an example of a deposition apparatus.

FIG. 2 is a plan view illustrating an example of a deposition apparatus.

FIG. 3 is a plan view illustrating an example of a deposition apparatus.

FIG. 4 is a plan view illustrating an example of a precursor supplying process of a positive polarity sub-cycle in a deposition apparatus.

FIG. 5 is a plan view illustrating an example of a purge process after supplying a precursor of a positive polarity sub-cycle in a deposition apparatus.

FIG. 6 is a plan view illustrating an example of a reactant supplying process of a positive polarity sub-cycle in a deposition apparatus.

FIG. 7 is a plan view illustrating an example of a purge process after supplying a reactant of a positive polarity sub-cycle in a deposition apparatus.

FIG. 8 is a plan view illustrating an example of a precursor supplying process of a negative polarity sub-cycle in a deposition apparatus.

FIG. 9 is a plan view illustrating an example of a purge process after supplying a precursor of a negative polarity sub-cycle in a deposition apparatus.

FIG. 10 is a plan view illustrating an example of a reactant supplying process of a negative polarity sub-cycle in a deposition apparatus.

FIG. 11 is a plan view illustrating an example of a purge process after supplying a reactant of a negative polarity sub-cycle in a deposition apparatus.

FIG. 12 is a flowchart for explaining an example of a deposition process of a deposition apparatus.

FIG. 13 is a graph for explaining an example of a deposition process of a deposition apparatus.

FIG. 14 is a graph for explaining an example of a deposition process of a deposition apparatus.

FIG. 15 is a graph for explaining an example of a deposition process of a deposition apparatus.

### DETAILED DESCRIPTION

Prior to the detailed description of the present disclosure, terms or words used in the specification and claims may not be construed as limited to their common or dictionary meanings. Further, the terms or words should be interpreted with meaning and concept consistent with the technical idea of the present disclosure based on the principle that the inventor may appropriately define the concept of terms in order to explain his or her invention in the best way. The example implementations described in this specification and the configurations shown in the drawings are only the most preferred implementations of the present disclosure, and do not necessarily represent the entire technical idea of the present disclosure. Accordingly, at the time of filing the present disclosure, there may be various equivalents and modifications that can replace them.

The same reference numeral or sign shown in each drawing attached to the specification may represent parts or components that perform substantially the same function. For convenience of description and understanding, different implementations may be described using the same reference numerals or symbols. In other words, even if a component or an element having the same reference numeral is shown in multiple drawings, the multiple drawings may not all represent one example implementation.

In the present disclosure, when an element is described as being “directly on,” “adjacent to” or “in contact with” another element, the element may be understood as being in direct contact with or connected to the another element, and it may be understood that there is no other element between the two.

Further, in the present disclosure, when an element is described as being “on an upper portion” or “on an upper surface” of another element, it may be understood as existing above the vertical direction, for example, as being above the +D1 direction in the drawing, and the two elements may be in direct contact or connected, but it may also be understood that another element exists between the two. The same is applied even when an element is described as being “above” another element in the present disclosure.

Further, in the present disclosure, when an element is described as being “on a lower portion” or “on a lower surface” of another element, it may be understood as existing below based on the vertical direction, for example, being further below based on the −D1 direction in the drawing, and the two elements may be in direct contact or connected, but it may also be understood that another element exists between the two. The same is applied even when an element is described as being “below” another element.

Other similar expressions describing the positional relationship between elements can also be interpreted similarly as above.

In the following description, singular expressions include plural expressions unless the context clearly dictates otherwise. It will be understood that, when an element (for example, a first element) is “(operatively or communicatively) coupled with/to” or “connected to” another element (for example, a second element), the element may be directly coupled with/to another element, and there may be an intervening element (for example, a third element) between the element and another element. The terms “have,” “may have,” “include,” and “may include” as used herein indicate the presence of corresponding features (for example, elements such as numerical values, functions, operations, or parts), and do not preclude the presence of additional features.

Further, in the following description, expressions such as upper side, upper surface, lower side, lower surface, side, a front side and a back side are expressed based on the direction shown in the drawing. If the direction of the object changes, it may be expressed differently.

Further, in the specification and claims, terms including ordinal numbers such as “first,” “second,” etc. may be used to distinguish between components or elements. These ordinal numbers are used to distinguish identical or similar components from each other, and the meaning of the terms should not be interpreted limitedly due to the use of such ordinal numbers. For example, components or elements combined with these ordinal numbers should not be interpreted as having a limited order of use or arrangement based on the number. If necessary, each ordinal number may be used interchangeably.

The drawings illustrated in the present disclosure are according to mere example implementations, and the ratio of the width, the length and the height (or the thickness) of each element is for detailed descriptions for the example implementations, and thus the ratio may differ from reality. Further, in the coordinate system illustrated in the drawings, each axis may be perpendicular to each other, and the direction the arrow points may be the +direction, and the direction opposite to the direction indicated by the arrow (rotated by 180 degrees) may be the −direction.

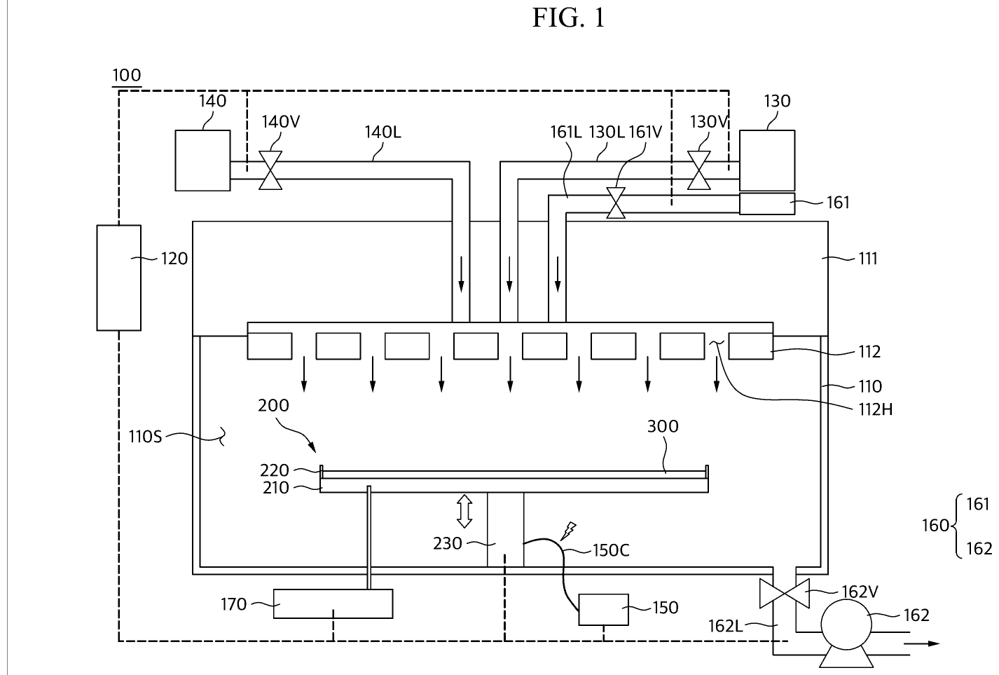

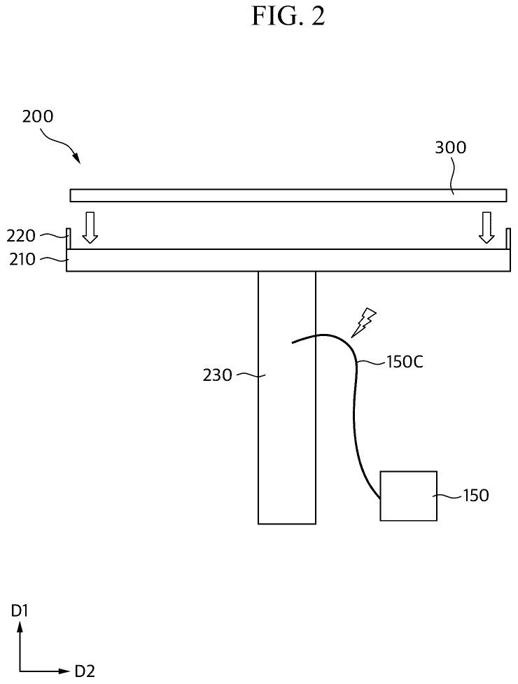

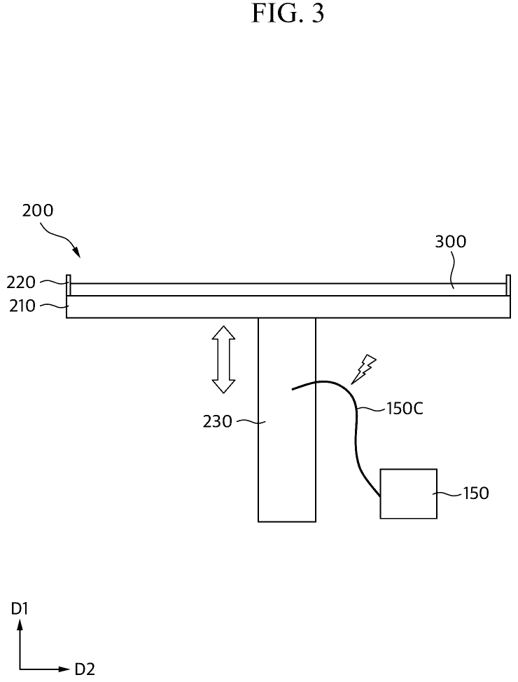

FIG. 1 is a plan view illustrating an example of a deposition apparatus 100. FIG. 2 is a plan view illustrating an example of the deposition apparatus 100. FIG. 3 is a plan view illustrating an example of the deposition apparatus 100.

The deposition apparatus 100 according to example implementations may be described based on an atomic layer deposition apparatus for convenience of explanation. In other words, the deposition apparatus 100 in some implementations may be an atomic layer deposition apparatus. However, in some implementations, the deposition apparatus 100 is not limited to an atomic layer deposition apparatus, and other types of deposition apparatus may also be utilized.

In some implementations, the deposition apparatus 100 may include a chamber 110 defining at least a portion of a processing space 110S in which a deposition process is performed on a substrate 300. In some implementations, the processing space 110S may be sealed.

In some implementations, the deposition apparatus 100 may include a lid 111. In some implementations, the deposition apparatus 100 may form the processing space 110S sealed by the chamber 110 and the lid 111.

In some implementations, the outer structure of the chamber 110 may have a cylinder, an elliptical column, or a polygonal column shape, but the outer structure of the chamber 110 is not limited thereto. Further, the chamber 110 may contain a metal material, and the electrical ground state may be maintained to block noise from the outside.

In some implementations, the chamber 110 may accommodate a voltage application part 200 including a stage 210 that accommodates the substrate 300. The voltage application part 200 can be called a voltage applicator.

Meanwhile, in some implementations, the substrate 300 is not particularly limited, but may be a silicon semiconductor substrate, a plastic substrate, a glass substrate, a compound semiconductor substrate, or a ceramic substrate.

In some implementations, the deposition apparatus 100 may include the lid 111 disposed on the chamber 110. In some implementations, the lid 111 may be placed on the chamber 110 to form the sealed processing space 110S as described above. The lid 111 may include a metal material such as, but is not limited to, aluminum. Additionally, the lid 111 may be maintained in an electrical ground state to block noise applied from the outside.

In some implementations, the deposition apparatus 100 may include a distribution supply part 112 for distribution. The distribution supply part 112 for distribution may include a plurality of holes 112H arranged to allow fluid to move. The distribution supply part 112 for distribution may evenly supply or distribute fluid (for example, gas phase material) supplied from a precursor supply part 130, a reactant supply part 140, and a purge apparatus 160, which will be described later, to the processing space 110S. The distribution supply part 112 can be called a distribution supplier. The precursor supply part 130 can be called a precursor supplier. The reactant supply part 140 can be called a reactant supplier.

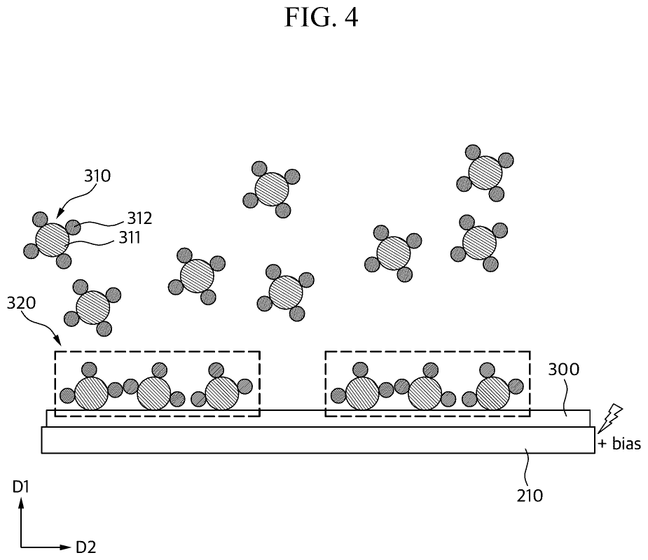

In some implementations, the deposition apparatus 100 may include the precursor supply part 130 that supplies a precursor 310 (of FIG. 4) into the chamber 110. A path 130L may be arranged between the precursor supply part 130 and the processing space 110S within the chamber 110 to allow fluid to flow. In some implementations, the path 130L may be formed through the lid 111. The precursor supply part 130 may include a pump for easily supplying the precursor 310 (of FIG. 4) into the chamber 110, and the pump may apply pressure to force the precursor 310 (of FIG. 4) through the path 130L. Further, a valve 130V may be placed between the paths 130L. The pump and the valve 130V may be individually controlled by electrical signals and so on by a controller 120 described later. Through this, the precursor supply part 130 may smoothly supply the precursor 310 (of FIG. 4) into the chamber 110 when necessary.

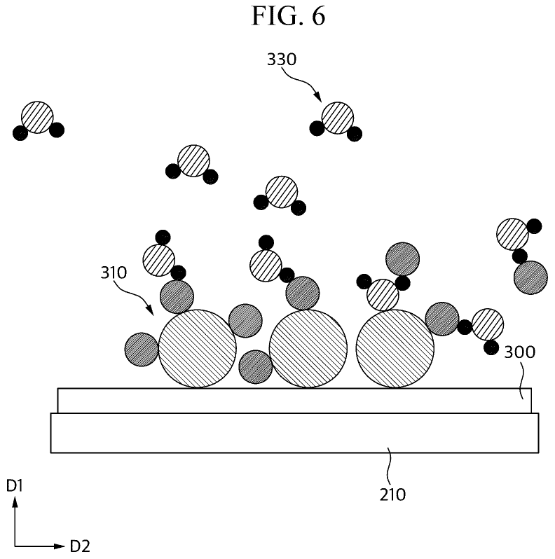

In some implementations, the deposition apparatus 100 may include the reactant supply part 140 that supplies reactant 330 (of FIG. 6) into the chamber 110. A path 140L may be arranged between the reactant supply part 140 and the processing space 110S within the chamber 110 to allow fluid to flow. In some implementations, the path 140L may be formed through the lid 111. The reactant supply part 140 may include a pump for easily supplying the reactant 330 (of FIG. 6) into the chamber 110, and the pump may apply pressure to force the reactant 330 (of FIG. 6) through the path 140L. Further, a valve 140V may be placed between the paths 140L. The pump and the valve 140V may be individually controlled by electrical signals and so on by the controller 120 described later. Through this, the reactant supply part 140 may smoothly supply the reactant 330 (of FIG. 6) into the chamber 110 when necessary.

Meanwhile, in some implementations, each of the valve 130V and the valve 140V arranged in the precursor supply part 130 and the reactant supply part 140 may include a controller (for example, a mass flow controller (MFC)) for controlling the amount of the precursor 310 (of FIG. 4) or the reactant 330 (of FIG. 6) flowing into the chamber 110. The controller may be controlled for operation by electrical signals and so on by the controller 120, which will be described later.

In some implementations, the voltage application part 200 may be contained within the chamber 110. The voltage application part 200 may include the stage 210 accommodating the substrate 300. In some implementations, the stage 210 may include a fixing part 220 positioned at an edge, and fix the position of the substrate 300 by placing the substrate 300 in a substrate receiving part 210H formed by the fixing part 220. In some implementations, the stage 210 itself could be a chuck. For example, the stage 210 may be an electrostatic chuck that positions and fixes the substrate 300 mounted on the stage 210 via static electricity, or a vacuum chuck that positions and fixes the substrate 300 mounted on the stage 210 via vacuum. The structure of the stage 210 is not particularly limited as long as the structure includes a space in which the substrate 300 is placed and the placed substrate 300 is fixed in the position.

In some implementations, the voltage application part 200 may include a lifting apparatus 230 supporting the stage 210. The lifting apparatus 230 may be arranged to move the stage 210 in a first direction D1 perpendicular to the surface of the stage 210. The substrate 300 may be placed in a position advantageous for deposition through the lifting apparatus 230. The lifting apparatus 230 may be controlled for operation by electrical signals and so on by the controller 120 described later.

In some implementations, the voltage application part 200 may include a voltage generator 150. The voltage generator 150 may be electrically connected to the stage 210 to apply a bias voltage to the substrate 300.

In some implementations, the voltage generator 150 may generate a bias voltage and provide the bias voltage to the stage 210. The voltage generator 150 may be electrically connected to the lifting apparatus 230. In other words, the bias voltage generated from the voltage generator 150 may be provided to the stage 210 through the lifting apparatus 230. Here, each of the lifting apparatus 230 and the stage 210 may be electrically connected and include a conductive region including a conductive material, and the voltage generator 150 may be connected to the conductive area of the lifting apparatus 230. Further, the voltage generator 150 may deliver bias voltage to the lifting apparatus 230 through a connecting part 150C. Here, the connecting part 150C may have a length sufficient to smoothly transmit the bias voltage even with the operation of the lifting apparatus 230. Further, the connecting part 150C may have an appropriate length so that efficient bias voltage may be transmitted, taking into account heat loss due to resistance due to length.

In some implementations, the voltage application part 200 may apply a bias voltage to the substrate 300. Here, the bias voltage applied by the voltage application part 200 to the substrate 300 is not particularly limited, but a direct current (DC) voltage may be beneficial to the uniformity of the thin film to be formed.

In some implementations, the voltage application part 200 may apply a positive electric field bias or a negative electric field bias to the substrate 300. Operation of the voltage application part 200 may be controlled by electrical signals and so on by the controller 120, which will be described later.

In some implementations, the deposition apparatus 100 may include the controller 120 that controls bias voltage applied to the substrate 300, flow of the precursor 310 (of FIG. 4), and flow of the reactant 330 (of FIG. 6). The control range of the controller 120 is not limited to the bias voltage applied to the substrate 300, the flow of the precursor 310 (of FIG. 4), and the flow of the reactant 330 (of FIG. 6), and all components in the deposition apparatus 100 whose operation may be controlled by electrical signals may be controlled by the controller 120.

In some implementations, the deposition apparatus 100 may include the purge apparatus 160 for purging residual material within the chamber 110. The purge apparatus 160 may include a gas injection apparatus 161 for injecting nitrogen (N₂) or an inert gas that does not react with the precursor 310 (in FIG. 4) or the reactant 330 (in FIG. 6). In some implementations, the purge apparatus 160 may include a discharging pump 162 to forcefully discharge any remaining material inside to the outside. The purge apparatus 160 may include the gas injection apparatus 161 and the discharging pump 162.

In some implementations, a path 161L may be arranged between the gas injection apparatus 161 and the processing space 110S within the chamber 110 to allow fluid to flow. In some implementations, the path 161L may be formed through the lid 111. The gas injection apparatus 161 may include a pump to easily supply nitrogen (N₂) or inert gas into the chamber 110, and the pump may pressurize nitrogen (N₂) or inert gas to pass through the path 161L. Further, a valve 161V may be placed between the paths 161L. Each of the pump and the valve 161V may be individually controlled by electrical signals and so on by the controller 120. Through this, the gas injection apparatus 161 may smoothly supply nitrogen (N₂) or inert gas into the chamber 110.

In some implementations, the deposition apparatus 100 may include a path 162L to allow fluid to flow between the processing space 110S within the chamber 110 and the exterior. Any remaining material inside the chamber 110 may be purged to the outside through the path 162L. The deposition apparatus 100 may include the discharging pump 162 so that the remaining material inside the chamber 110 may be easily discharged to the outside through the path 162L. The discharging pump 162 may apply pressure so that the remaining material inside the chamber 110 may be discharged to the outside through the path 162L. At this time, the remaining material inside may be discharged to the outside more easily by the gas injection apparatus 161 described above. Further, a valve 162V may be placed between the paths 162L. Each of the discharging pump 162 and the valve 162V may be individually controlled by electrical signals and so on by the controller 120.

In some implementations, the deposition apparatus 100 may include a heating apparatus 170 that delivers thermal energy to the stage 210. The heating apparatus 170 may be located outside of the chamber 110. The heating apparatus 170 may transfer thermal energy to the stage 210, and the thermal energy transferred to the stage 210 may be transferred to the substrate 300, thereby heating the substrate 300.

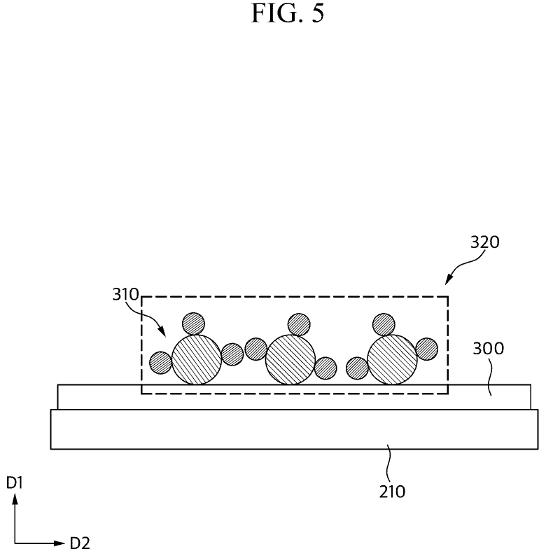

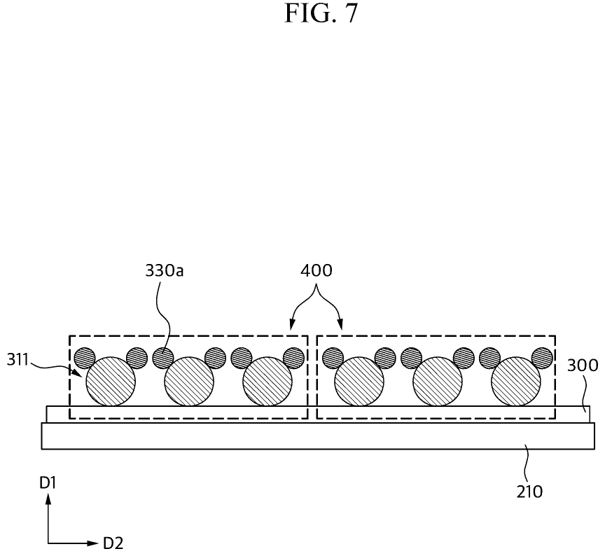

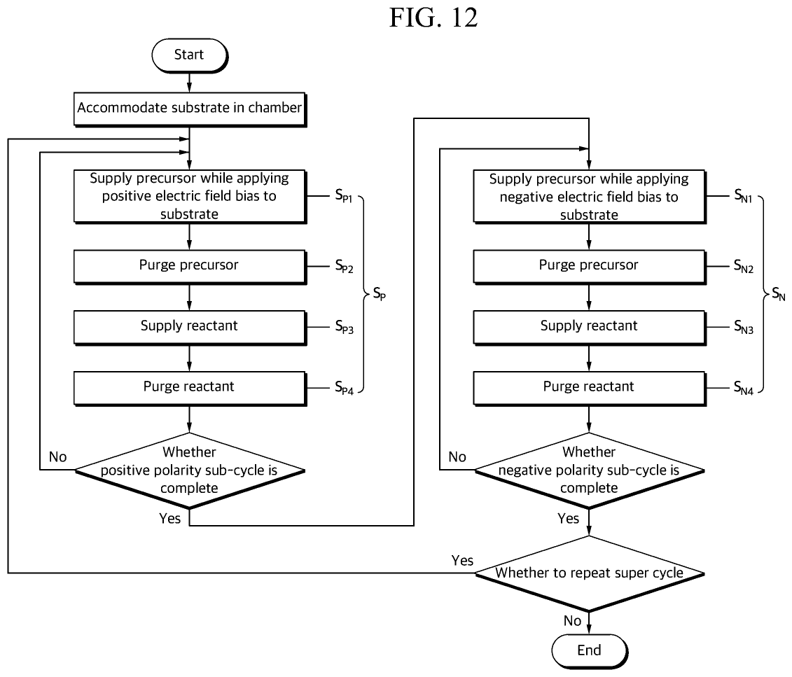

FIG. 4 is a plan view illustrating an example of a precursor supplying process (see operation S_{P1} of FIG. 12) of a positive polarity sub-cycle S_{P} (of FIG. 12) in the deposition apparatus 100. FIG. 5 is a plan view illustrating an example of a purge process (see operation S_{P2} of FIG. 12) after precursor supply of the positive polarity sub-cycle S_{P} (of FIG. 12) in the deposition apparatus 100. FIG. 6 is a plan view illustrating an example of a reactant supplying process (see operation S_{P3} of FIG. 12) of the positive polarity sub-cycle S_{P} (of FIG. 12) in the deposition apparatus 100. FIG. 7 is a plan view illustrating an example of a purge process (see operation S_{P4} of FIG. 12) after supplying reactant in the positive polarity sub-cycle S_{P} (of FIG. 12) in the deposition apparatus 100.

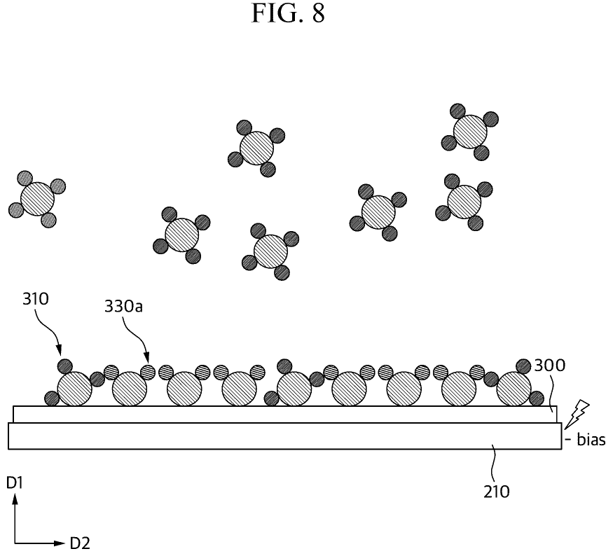

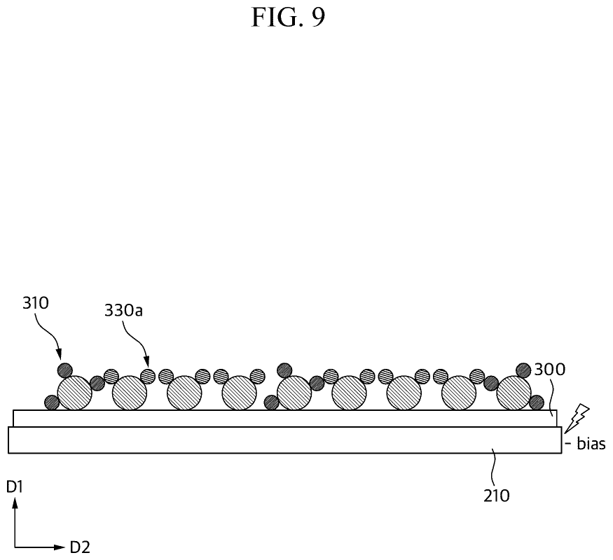

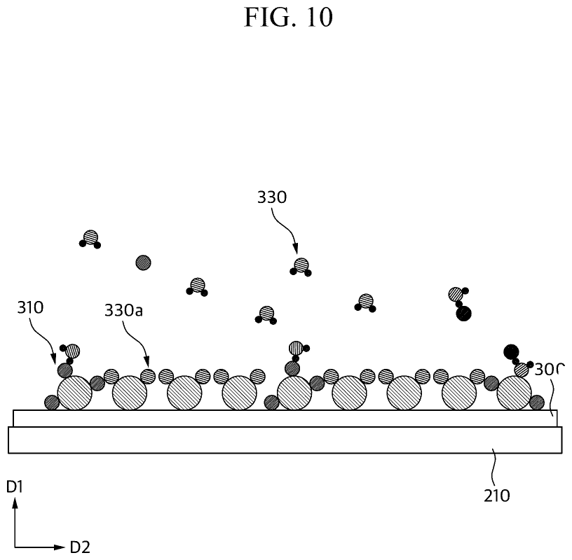

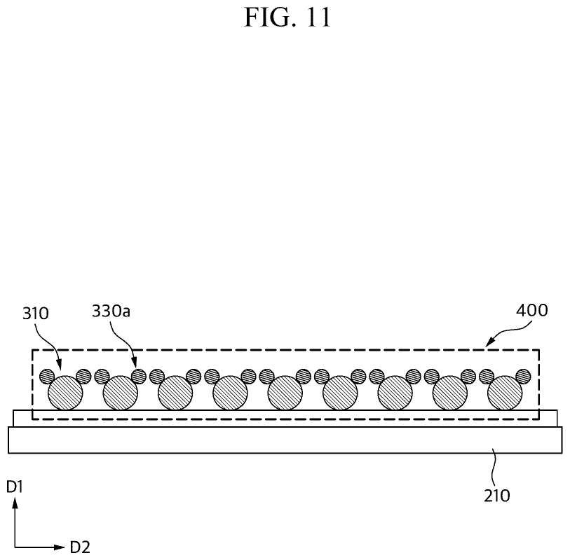

FIG. 8 is a plan view illustrating an example of a precursor supplying process (see operation S_{N1} of FIG. 12) of a negative polarity sub-cycle S_{N} (of FIG. 12) in the deposition apparatus 100. FIG. 9 is a plan view illustrating an example of a purge process (see operation S_{N2} of FIG. 12) after precursor supply of the negative polarity sub-cycle S_{N} (of FIG. 12) in the deposition apparatus 100. FIG. 10 is a plan view illustrating an example of a reactant supplying process (see operation S_{N3} of FIG. 12) of the negative polarity sub-cycle S_{N} (of FIG. 12) in the deposition apparatus 100. FIG. 11 is a plan view illustrating an example of a purge process (see operation S_{N4} of FIG. 12) after supplying reactant of the negative polarity sub-cycle S_{N} (of FIG. 12) in the deposition apparatus 100.

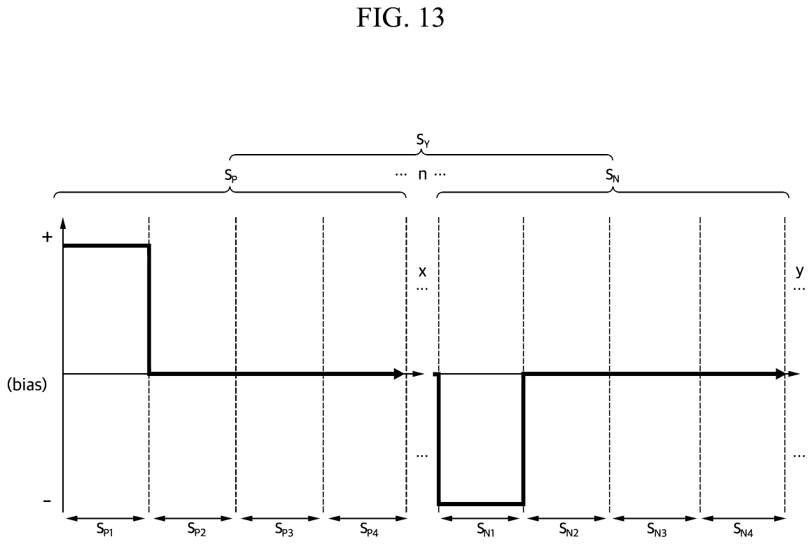

FIG. 12 is a flowchart illustrating an example of a deposition process of the deposition apparatus 100. FIG. 13 is a graph for explaining an example of a deposition process of the deposition apparatus 100.

In the deposition apparatus 100 according to one implementation of the present disclosure, the controller 120 may control a series of sub-cycles. In some implementations, the controller 120 may cause the precursor supply part 130 to supply the precursor 310 into the chamber 110. After then, the controller 120 may purge the remaining precursor 310 that is not bound to the substrate 300 within the chamber 110. In other words, the controller 120 may be controlled to purge the remaining precursor 310 that is not bound to the substrate 300 within the chamber 110 by stopping the precursor supply part 130 from supplying precursor into the chamber 110 and operating the purge apparatus 160. Meanwhile, as will be described later, the controller 120 may control multiple sub-cycles. In this case, the controller 120 may purge the remaining precursor 310 that is not bound to the substrate 300 or the remaining precursor 310 that is not bound to the previously formed deposition layer 400. In other words, in the present disclosure, purging the remaining precursor 310 that is not bound to the substrate 300 may include the concept of purging the remaining precursor 310 that is not bound to the substrate 300 as well as the previously formed deposition layer 400. After then, the controller 120 may control the reactant supply part 140 to supply the reactant 330 into the chamber 110. In other words, the controller 120 may perform the purge process enough to ensure that no residual precursor 310 remains within the chamber 110, and the controller 120 may stop the operation of the purge apparatus 160 and operate the reactant supply part 140 to supply the reactant 330 into the chamber 110. After then, the controller 120 may control for purging the residual reactant 330 that did not react with the precursor 310 and by-product of reaction in the chamber 110. In other words, the controller 120 may stop the reactant supply part 140 from supplying the reactant 330 into the chamber 110, and operate the purge apparatus 160 to purge the residual reactant 330 and by-product of reaction within the chamber 110. The controller 120 may include a circuit configured to perform a process described herein. The controller 120 may include dedicated circuitry or may include, for example, a central processing unit (CPU) chip, a graphic processing unit (GPU) chip, an application processor (AP) chip, an application specific integrated circuit (ASIC), or other processing chips.

In some implementations, the precursor 310 may exist in a solid state in the precursor supply part 130, and the precursor 310 may be sublimated into a gaseous state when supplied to the chamber 110. The precursor 310 may include a central metal 311 and a nonmetal 312 combined with the central metal 311. The nonmetal 312 may be of one type or of two or more types, and may be an element or atomic group ionically bonded to the central metal 311, or a ligand coordinately bonded to the central metal 311.

In some implementations, the precursor 310 may be polar. In some implementations, the deposition apparatus 100 may be more suitable for the polar precursor 310. When the polar precursor 310 is supplied, by applying a bias voltage to the substrate 300, the uniformity of the thin film may be secured, the impingement rate of the precursor 310 may be prevented from decreasing, and the resistivity may be reduced.

In some implementations, when two or more types of nonmetal 312 are supplied and the polar precursor 310 is supplied, by applying a bias voltage to the substrate 300, the uniformity of the thin film is ensured, the impingement rate of the precursor 310 is prevented from decreasing, and the resistivity may be reduced.

In some implementations, the controller 120 may control a super cycle S_{Y} to be performed that includes at least once each of the positive polarity sub-cycle S_{P} in which positive electric field bias is applied to the substrate 300 when the precursor 310 is supplied into the chamber 110 and the negative polarity sub-cycle S_{N} in which negative electric field bias is applied to the substrate 300 when the precursor 310 is supplied into the chamber 110. Through this, minimized may be the problem that when only a positive electric field bias is applied, the resistance increases due to the increase in grain boundary caused by the generation of excessive precursor nuclei 320, and that when only a negative electric field bias is applied, resistance increases or power cut occurs due to the creation of low-density voids.

Specifically, the controller 120 may control the voltage application part 200 to apply a positive electric field bias to the substrate 300 while controlling the precursor supply part 130 to provide the precursor 310 into the chamber 110. Further, the controller 120 control the voltage application part 200 to apply the negative electric field bias to the substrate 300 while controlling the precursor supply part 130 to provide the precursor 310 into the chamber 110. Here, the controller 120 may not control that the voltage application part 200 applies the positive electric field bias and the negative electric field bias simultaneously or crosswise to the substrate 300 while the precursor supply part 130 supplies the precursor 310 into the chamber 110. In other words, for example, the controller 120 may not control with the cross application method in which the positive electric field bias is applied to the substrate 300 and the negative electric field bias is applied again within one sub-cycle as the precursor 310 is supplied into the chamber 110. The controller 120 applying only the positive electric field bias or only the negative electric field bias to the substrate 300 within one sub-cycle may be more advantageous in terms of the uniformity of the thin film being secured, the impingement rate of the precursor 310 being prevented, and the resistivity being reduced.

In some implementations, the controller 120 may control the voltage application part 200 to apply the positive electric field bias or the negative electric field bias to the substrate 300 for the same period of time that the precursor supply part 130 supplies the precursor 310 into the chamber 110.

In some implementations, the controller 120 may apply or not apply a bias voltage to the substrate 300 when purging the residual precursor 310. This may vary depending on design.

In some implementations, the controller 120 may cause the reactant supply part 140 to supply the reactant 330 into the chamber 110 while causing the voltage application part 200 to apply or not apply a bias voltage to the substrate 300. This may vary depending on design.

In some implementations, the reactant 330 is not particularly limited as long as it is a substance that reacts with the nonmetal 312 of the precursor 310. For example, the reactant 330 may include water vapor (H₂O), ammonia (NH₃), oxygen (O₂), or hydrogen (H₂). In some implementations, after the reactant 330 reacts with the nonmetal 312 of the precursor 310, some elements 330a constituting the reactant 330 may be combined with the central metal 311.

In some implementations, the controller 120 may control applying or not applying a bias voltage to the substrate 300 when the residual reactant 330 and by-product of reaction are purged. This may vary depending on design.

In some implementations, the controller 120 may control the super cycle S_{Y} starting with the positive polarity sub-cycle S_{P}. The controller 120 may control the voltage application part 200 to start with the positive polarity sub-cycle S_{P} in which a positive electric field bias is applied to the substrate 300, followed by the negative polarity sub-cycle S_{N} in which a negative electric field bias is applied to the substrate 300, while controlling the precursor supply part 130 to supply the precursor 310 into the chamber 110.

In some implementations, the controller 120 may control the precursor supply part 130 to supply the precursor 310 into the chamber 110 while applying a positive electric field bias to the substrate 300 in operation S_{P1}. In this process, the precursor 310 may be bonded to the substrate 300, when the precursor 310 is polar, it may be more advantageous to form precursor nuclei 320 on the substrate 300 (see FIG. 4 and FIG. 5). After then, the controller 120 may control purging the remaining precursor 310 not bound to the substrate 300 within the chamber 110 in operation S_{P2}. In this process, bias may not be applied to the substrate 300, or when the bias is applied to the substrate 300, the positive electric field bias may also be applied. After then, the controller 120 may control the reactant supply part 140 to supply the reactant 330 into the chamber 110 in operation S_{P3}. In this process, bias may not be applied to the substrate 300, but when the bias is applied to the substrate 300, the positive electric field bias may be applied. After then, the controller 120 may control in order for the residual reactant 330 that did not react with the precursor 310 in the chamber 110 and by-product of reaction to be purged in operation S_{P4}. In this process, bias may not be applied to the substrate 300, but when the bias is applied to the substrate 300, the positive electric field bias may be applied.

In some implementations, the controller 120 may perform the positive polarity sub-cycle S_{P} once or more times. For example, the controller 120 may perform the positive polarity sub-cycles S_{P} x time or more times (where x is 1 or more). The prescribed number of executions (x) of the positive polarity sub-cycle S_{P} may be determined in advance. When the number of executions of the positive polarity sub-cycle S_{P} is equal to the prescribed number of executions (x), the controller 120 may determine that the positive polarity sub-cycle S_{P} is complete. When the number of executions of the positive polarity sub-cycle S_{P} is less than the prescribed number of executions (x), the controller 120 may again perform the positive polarity sub-cycle S_{P}.

In some implementations, the controller 120 may form the precursor nuclei 320 on the substrate 300 by performing the positive polarity sub-cycle S_{P} as described above. The controller 120 may repeatedly perform the positive polarity sub-cycle S_{P} in order for the precursor nuclei 320 to cover 50% or more than 50% of the surface of the substrate 300. In other words, the prescribed number of executions (x) of the positive polarity sub-cycle S_{P} may be a number of times by which the precursor nuclei 320 covers 50% or more than 50% of the surface of the substrate 300.

In some implementations, the controller 120 may control the super cycle S_{Y} in which after the positive polarity sub-cycle S_{P} is performed once or more times, the negative polarity sub-cycle S_{N} is performed once or more times. In other words, the controller 120 may control the super cycle S_{Y} in which the positive polarity sub-cycle S_{P} begins, followed by the negative polarity sub-cycle S_{N}.

In some implementations, the controller 120 may control the precursor supply part 130 to supply the precursor 310 into the chamber 110 while applying the negative electric field bias to the substrate 300 in operation S_{N1}. In this process, the precursor 310 may be bonded to the substrate 300, and it may be more advantageous to form the continuous deposition layer 400 by connecting the precursor nuclei 320 formed in the positive polarity sub-cycle S_{P}. After then, the controller 120 may control in order for the remaining precursor 310 that is not bound to the substrate 300 in the chamber 110 to be purged in operation S_{N2}. In this process, bias may not be applied to the substrate 300, but when the bias is applied to the substrate 300, the negative electric field bias may be applied. After then, the controller 120 may control the reactant supply part 140 to supply the reactant 330 into the chamber 110 in operation S_{N3}. In this process, bias may not be applied to the substrate 300, but when the bias is applied to the substrate 300, the negative electric field bias may be applied. After then, the controller 120 may control in order for the remaining reactant 330 that did not react with the precursor 310 and by-products of reaction to be purged in operation S_{N4}. In this process, the bias may not be applied to the substrate 300, but when the bias is applied to the substrate 300, the negative electric field bias may be applied.

Meanwhile, in some implementations, the deposition layer 400 may be a thin film to be formed through the deposition apparatus 100. The deposition layer 400 may be formed by depositing an ionic compound of the central metal 311 on the substrate 300. Here, the ionic compound may include oxides, halides, or nitrides of the central metal 311, but is not limited thereto. Meanwhile, the deposition apparatus 100 may not only form the deposition layer 400 on the substrate 300, but may also form an additional deposition layer 400 on the deposition layer 400 already deposited on the substrate 300. In other words, depositing an ionic compound of the central metal 311 on the substrate 300 may include the concept of depositing on the substrate 300 as well as on the previously formed deposition layer 400.

In some implementations, the controller 120 may perform the negative polarity sub-cycle S_{N} once or more times. For example, the controller 120 may perform the negative polarity sub-cycle S_{N} y time or more times (y is 1 or more). The prescribed number of executions (y) of the negative polarity sub-cycle S_{N} may be determined in advance. When the number of executions of the negative polarity sub-cycle S_{N} is equal to the prescribed number of executions (y), the controller 120 may determine that the negative polarity sub-cycle S_{N} is complete. When the number of executions of the negative polarity sub-cycle S_{N} is less than the prescribed number of executions (y), the controller 120 may again perform the negative polarity sub-cycle S_{N}.

In some implementations, the controller 120 may control the negative polarity sub-cycle S_{N} to be performed in order for the continuous deposition layer 400 to be formed by connecting the precursor nuclei 320 formed on the substrate 300. By the negative polarity sub-cycle S_{N} being performed, crystal of the pre-formed precursor nuclei 320 may be grown. The controller 120 may perform the negative polarity sub-cycle S_{N} repeatedly in order for the continuous deposition layer 400 to cover the entire surface of the substrate 300 and the thickness of the deposition layer 400 to increase. In other words, the prescribed number of executions (y) of the negative polarity sub-cycle S_{N} may be a number of times by which the continuous deposition layer 400 covers the entire surface of the substrate 300 and the thickness of the deposition layer 400 increases.

In some implementations, the controller 120 may perform the super cycle S_{Y} once or more times which includes the positive polarity sub-cycle S_{P} and the negative polarity sub-cycle S_{N} that are described above. For example, the controller 120 may perform the super cycle S_{Y} n time or more times (n is 1 or more). The prescribed number of executions (n) of the super cycle S_{Y} may be determined in advance. When the number of executions of the super cycle S_{Y} is equal to the prescribed number of executions (n), the controller 120 may determine that the super cycle S_{Y} is complete. In this case, the controller 120 may terminate the deposition process. When the number of executions of the super cycle S_{Y} is less than the prescribed number of executions (n), the controller 120 may again perform the super cycle S_{Y} including the positive polarity sub-cycle S_{P} and the negative polarity sub-cycle S_{N}.

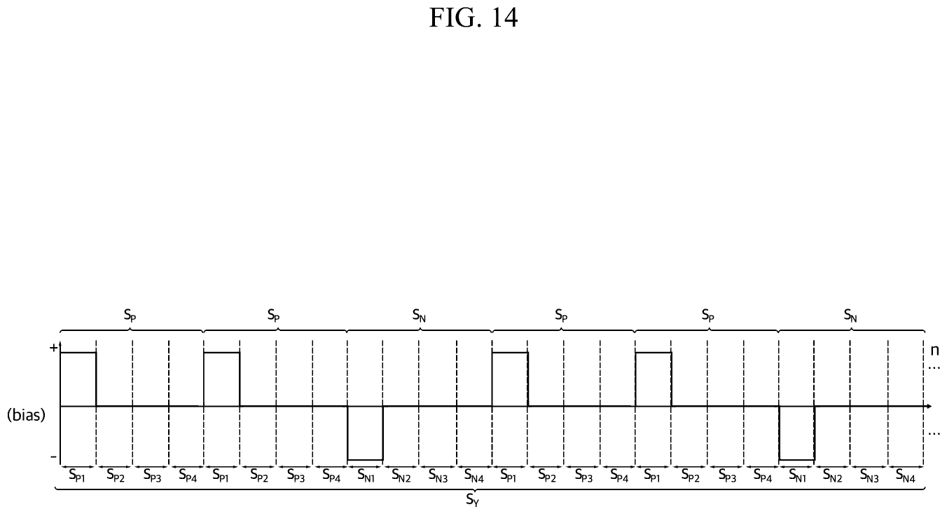

FIG. 14 is a graph for explaining an example of a deposition process of the deposition apparatus 100. Referring to FIG. 14, an example implementation of the super cycle S_{Y} controlled by the controller 120 is identified.

In some implementations, for every one time super cycle S_{Y}, the controller 120 may control the positive polarity sub-cycles S_{P} to be performed two times and then, the negative polarity sub-cycle S_{N} to be performed once, and the controller 120 may control the super cycle S_{Y} that is performed n times. In some implementations, the controller 120 may control the super cycle S_{Y} starting from the positive polarity sub-cycle S_{P} as described above.

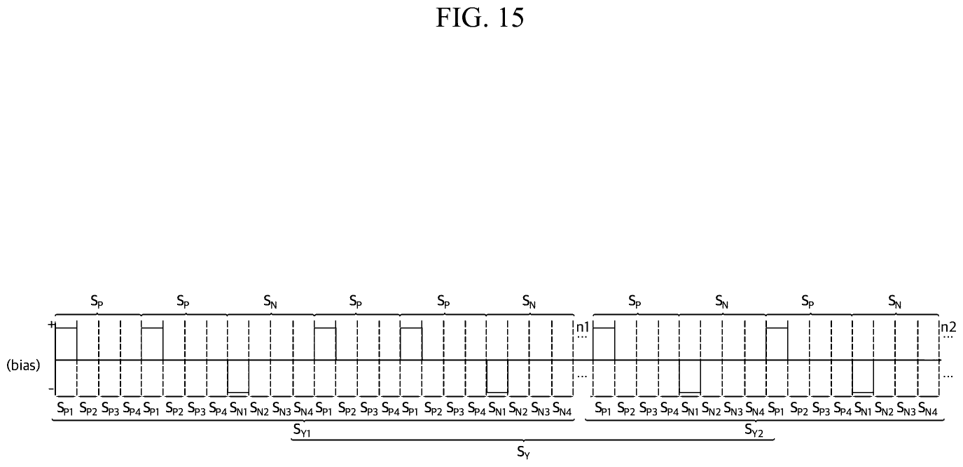

FIG. 15 is a graph for explaining an example of a deposition process of the deposition apparatus 100.

In the deposition apparatus 100 according to example implementations, the controller 120 may control the super cycle S_{Y} to be performed multiple times, in which each of the prescribed number of executions of the positive polarity sub-cycle S_{P} and prescribed number of executions of the negative polarity sub-cycle S_{N} is independent.

In some implementations, the controller 120 may control the super cycle S_{Y} including a first super cycle S_{Y1} in which the positive polarity sub-cycle S_{P} is performed x1 time or more times and the negative polarity sub-cycle S_{N} is performed y1 time or more times and a second super cycle S_{Y2} in which the positive polarity sub-cycle S_{P} is performed x₂ times or more and the negative polarity sub-cycle S_{N} is performed y₂ times or more. Here, each of x₁, x₂, y₁ and y₂ may independently be greater than or equal to 1. Further, each of x₁, x₂, y₁ and y₂ may independently be a prescribed number of executions.

In some implementations, the controller 120 may control the super cycle S_{Y} in which after the first super cycle S_{Y} is performed once or more times, the second super cycle S_{Y2} is performed once or more times. For example, the controller 120 may perform the first super cycle S_{Y1} n1 time or more times (n1 is 1 or more), and the prescribed number of executions n1 of the first super cycle S_{Y1} may be determined in advance. When the number of executions of the first super cycle S_{Y1} is equal to the prescribed number of executions n1, the controller 120 may determine that the first super cycle S_{Y1} is complete. Further, when it is determined that the first super cycle S_{Y1} is completed, the controller 120 may control the second super cycle S_{Y2} to be performed n2 time or more times (n2 is 1 or more). The prescribed number of executions n2 of the second super cycle S_{Y2} may be determined in advance. When the number of executions of the second super cycle S_{Y2} is equal to the prescribed number of executions n2, the controller 120 may determine that the second super cycle S_{Y2} is complete.

In some implementations, the controller 120 may perform the super cycles S_{Y} once or more times, including the first super cycle S_{Y1} and the second super cycle S_{Y2}. For example, the controller 120 may perform the super cycle S_{Y} n time or more times (n is 1 or more). The prescribed number of executions n of the super cycle S_{Y} may be determined in advance. When the number of executions of the super cycle S_{Y} is equal to the prescribed number of executions n, the controller 120 may determine that the super cycle S_{Y} is complete. In this case, the controller 120 may terminate the deposition process. When the number of executions of the super cycle S_{Y} is less than the prescribed number of executions n, the controller 120 may perform the first super cycle S_{Y1} again.

In some implementations, the controller 120 may control in order for the prescribed number of executions x₁ of the positive polarity sub-cycle S_{P} in the first super cycle S_{Y1} to be the same as or greater than the prescribed number of executions x₂ of the positive polarity sub-cycle S_{P} in the second super cycle S_{Y2}.

In some implementations, the controller 120 may control in order for the prescribed number of executions x₁ of the positive polarity sub-cycle S_{P} in the first super cycle S_{Y1} to be greater than the prescribed number of executions x₂ of the positive polarity sub-cycle S_{P} in the second super cycle S_{Y2}.

Designing the prescribed number of executions x₁ of the positive polarity sub-cycle S_{P} within the first super cycle S_{Y1} to be greater than the prescribed number of executions x₂ of the positive polarity sub-cycle S_{P} within the second super cycle S_{Y2} may be more advantageous in forming the precursor nuclei 320 in the early stage of the deposition.

In some implementations, when the prescribed number of executions x₁ of the positive polarity sub-cycle S_{P} in the first super cycle S_{Y1} and the prescribed number of executions x₂ of the positive polarity sub-cycle S_{P} in the second super cycle S_{Y2} are the same, the controller 120 may control the prescribed number of executions y₁ of the negative polarity sub-cycle S_{N} within the first super cycle S_{Y1} to be a smaller number than the prescribed number of executions y₂ of the negative polarity sub-cycle S_{N} within the second super cycle S_{Y2}. Through this, minimized may be the problem that the thin film quality deteriorates as the crystals grow despite insufficient formation of the precursor nuclei 320.

In some implementations, the controller 120 may control the prescribed number of executions y₁ of the negative polarity sub-cycle S_{N} within the first super cycle S_{Y1} to be equal to or less than the prescribed number of executions y₂ of the negative polarity sub-cycle S_{N} within the second super cycle S_{Y2}.

In some implementations, the controller 120 may control the prescribed number of executions y₁ of the negative polarity sub-cycle S_{N} within the first super cycle S_{Y1} to be smaller than the prescribed number of executions y₂ of the negative polarity sub-cycle S_{N} within the second super cycle S_{Y2}. Through this, minimized may be the problem that the thin film quality deteriorates as the crystals grow despite insufficient formation of the precursor nuclei 320.

When the prescribed number of executions y₁ of the negative polarity sub-cycle S_{N} in the first super cycle S_{Y1} and the prescribed number of executions y₂ of the negative polarity sub-cycle S_{N} in the second super cycle S_{Y2} are the same, the controller 120 may control the prescribed number of executions x₁ of the positive polarity sub-cycle S_{P} within the first super cycle S_{Y1} to be greater than the prescribed number of executions x₂ of the positive polarity sub-cycle S_{P} within the second super cycle S_{Y2}. Through this, a more advantageous design may be achieved for forming the precursor nuclei 320 in the early stage of deposition.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The example implementations of the present disclosure are described with reference to the attached drawings. However, the present disclosure is not limited to the example implementations, and the present disclosure can be manufactured in various other forms, and a person skilled in the art to which the present disclosure pertains will understand that the present disclosure can be implemented in other specific forms without changing its technical idea or essential features. Therefore, the example implementations described above should be understood in all respects as illustrative and not limiting.

What is claimed is:

1. A deposition apparatus comprising:
a chamber configured to accommodate a voltage applicator, the voltage applicator comprising a stage that is configured to accommodate a substrate;
a voltage generator that is electrically connected with the stage and configured to apply bias voltage to the substrate;
a precursor supplier configured to supply precursor into the chamber;
a reactant supplier configured to supply reactant into the chamber; and
a controller configured to control the bias voltage applied to the substrate, precursor flow, and reactant flow,
wherein the controller is configured to, for each sub-cycle of a plurality of sub-cycles:
cause the precursor supplier to supply the precursor into the chamber,
cause the chamber to purge remaining precursor that is not bound to the substrate in the chamber,
cause the reactant supplier to supply the reactant into the chamber, and
cause the chamber to purge remaining reactant that is not reacted with the precursor in the chamber and by-product of reaction; and
wherein the controller is configured to:
for each positive polarity sub-cycle of a super cycle, cause a positive electric field bias to be applied to the substrate based on the precursor being supplied into the chamber, and
for each negative polarity sub-cycle of the super cycle, cause a negative electric field bias to be applied to the substrate based on the precursor being supplied into the chamber.

2. The deposition apparatus of claim 1, wherein the voltage applicator comprises a lifting apparatus configured to support the stage, and
wherein the voltage generator is electrically connected with the lifting apparatus.

3. The deposition apparatus of claim 2, wherein the lifting apparatus is configured to move the stage in a first direction perpendicular to a surface of the stage.

4. The deposition apparatus of claim 1, wherein the bias voltage applied to the substrate is direct current (DC) voltage.

5. The deposition apparatus of claim 1, wherein the precursor comprises central metal and nonmetal that is bonded with the central metal, and
wherein the precursor is polar.

6. The deposition apparatus of claim 5, wherein the nonmetal is of two or more types.

7. The deposition apparatus of claim 1, wherein the super cycle starts with a positive polarity sub-cycle.

8. The deposition apparatus of claim 1, wherein the super cycle starts with at least one positive polarity sub-cycle followed by at least one negative polarity sub-cycle.

9. The deposition apparatus of claim 8, wherein the controller is configured to:
cause precursor nuclei to be formed on the substrate based on performing the at least one positive polarity sub-cycle, and
cause a continuous deposition layer to be formed based on connecting the precursor nuclei formed on the substrate based on performing the at least one negative polarity sub-cycle.

10. The deposition apparatus of claim 9, wherein the controller is configured to perform the at least one positive polarity sub-cycle repeatedly until the precursor nuclei covers 50% or more of a surface of the substrate.

11. The deposition apparatus of claim 9, wherein the controller is configured to perform the at least one negative polarity sub-cycle repeatedly until the continuous deposition layer covers an entire surface of the substrate and thickness of the continuous deposition layer increases.

12. The deposition apparatus of claim 1, wherein the super cycle comprises a first super cycle and a second super cycle,
wherein the controller is configured to perform, in the first super cycle, a positive polarity sub-cycle at least x₁ times and a negative polarity sub-cycle at least y₁ times,
wherein the controller is configured to perform, in the second super cycle, a positive polarity sub-cycle at least x₂ times and a negative polarity sub-cycle at least y₂ times, and
wherein x₁, x₂, y₁, and y₂ are greater than or equal to 1.

13. The deposition apparatus of claim 12, wherein the controller is configured to control the super cycle to perform the second super cycle once or more times after performing the first super cycle one or more times.

14. The deposition apparatus of claim 13, wherein the controller is configured to control x₁ to be a number equal to or greater than x₂.

15. The deposition apparatus of claim 14, wherein the controller is configured to control x₁ to be equal to x₂, and to control y₁ to be a number smaller than y₂.

16. The deposition apparatus of claim 13, wherein the controller is configured to control y₁ to be a number equal to or less than y₂.

17. The deposition apparatus of claim 16, wherein the controller is configured to control y₁ to be equal to y₂, and to control x₁ to be a number greater than x₂.

18. A deposition apparatus comprising:
a chamber configured to accommodate a voltage applicator, the voltage applicator comprising a stage that is configured accommodate a substrate;
a voltage generator that is electrically connected with the stage and configured to apply bias voltage to the substrate;
a precursor supplier configured to supply precursor into the chamber, the precursor comprising central metal;
a reactant supplier configured to supply reactant into the chamber; and
a controller configured to control the bias voltage applied to the substrate, precursor flow, and reactant flow,
wherein the controller is configured to, for each sub-cycle of a plurality of sub-cycles:
cause the precursor supplier to supply the precursor into the chamber,
cause the chamber to purge remaining precursor that is not bound to the substrate in the chamber,
cause the reactant supplier to supply the reactant into the chamber, and
cause the chamber to purge remaining reactant that is not reacted with the precursor in the chamber and by-product of reaction;
wherein the controller is configured to:
for each positive polarity sub-cycle of a super cycle, cause a positive electric field bias to be applied to the substrate based on the precursor being supplied into the chamber, and
for each negative polarity sub-cycle of the super cycle, cause a negative electric field bias to be applied to the substrate based on the precursor being supplied into the chamber; and
wherein the controller is configured to cause an ionic compound of the central metal to be deposited on the substrate, thereby forming a deposition layer.

19. The deposition apparatus of claim 18, wherein the deposition apparatus is an atomic layer deposition apparatus.

20. A deposition apparatus comprising:
a chamber configured to accommodate a voltage applicator, the voltage applicator comprising a stage that is configured to accommodate a substrate;
a voltage generator that is electrically connected with the stage and configured to apply bias voltage to the substrate;
a precursor supplier configured to supply precursor into the chamber, the precursor comprising central metal;
a reactant supplier configured to supply reactant into the chamber; and
a controller configured to control the bias voltage applied to the substrate, precursor flow, and reactant flow,
wherein the controller is configured to, for each sub-cycle of a plurality of sub-cycles:
cause the precursor supplier to supply the precursor into the chamber,
cause the chamber to purge remaining precursor that is not bound to the substrate in the chamber,
cause the reactant supplier to supply the reactant into the chamber, and
cause the chamber to purge remaining reactant that is not reacted with the precursor in the chamber and by-product of reaction;
wherein the controller is configured to:
for each positive polarity sub-cycle of a super cycle, cause a positive electric field bias to be applied to the substrate based on the precursor being supplied into the chamber, and
for each negative polarity sub-cycle of the super cycle, cause a negative electric field bias to be applied to the substrate based on the precursor being supplied into the chamber;
wherein the controller is configured to:
cause precursor nuclei to be formed on the substrate based on performing the positive polarity sub-cycle,
cause a continuous deposition layer to be formed based on connecting the precursor nuclei formed on the substrate based on performing the negative polarity sub-cycle; and
wherein the controller is configured to:
control the super cycle to start with the positive polarity sub-cycle,
perform the positive polarity sub-cycle repeatedly until the precursor nuclei covers 50% or more of a surface of the substrate, and
perform the negative polarity sub-cycle repeatedly until the continuous deposition layer covers an entire surface of the substrate and thickness of the continuous deposition layer increases.
